(19) United States
(12) Patent Application Publication
(10) Pub. No.: US 2026/0047064 A1
(43) Pub. Date: Feb. 12, 2026

(54) SACRIFICIAL METAL SIGNAL OR POWER LINE

(71) Applicant: Applied Materials, Inc., Santa Clara, CA (US)

(72) Inventors: Zhijun CHEN, San Jose, CA (US); Raghuveer S. MAKALA, Campbell, CA (US); Jongbeom SEO, San Jose, CA (US); Fredrick FISHBURN, Belmont, CA (US)

(73) Assignee: Applied Materials, Inc., Santa Clara, CA (US)

(21) Appl. No.: 18/799,626

(22) Filed: Aug. 9, 2024

(51) Int. Cl. H10B 12/00; H01L 21/762; H01L 21/768

(52) U.S. Cl. CPC H10B 12/0335; H01L 21/76224; H01L 21/76879

(57) ABSTRACT

The present technology includes methods and systems for forming advanced memory structures, and devices therefrom. Methods include forming a dummy material layer over a first sidewall, a second sidewall, and a bottom surface, of one or more features, where the first sidewall is spaced apart from the second sidewall and the bottom surface is disposed between the first sidewall and the second sidewall. Methods include filling a gap formed between the dummy material on the first sidewall and the low resistivity material on the second sidewall with a sacrificial isolation material. Methods include removing at least a portion of the bottom surface, exposing at least a portion of the dummy material and the sacrificial isolation material. Methods include removing the sacrificial isolation material and at least a portion of the dummy material and selectively depositing a conductive material on a remaining portion of the dummy material.

### TECHNICAL FIELD

This disclosure generally describes designs for advanced memory devices, such as 4F² dynamic random-access memory (DRAM) arrays, 6F² DRAM arrays, 3D DRAM, 3D NAND, junction-less SONOS memory, floating body cell memory, oxide semiconductor memory, ferroelectric memory, and other advanced memory devices. More specifically, this disclosure describes advanced memory arrays with low signal or power line resistivity.

### BACKGROUND

With advances in computing technology, computing devices are smaller and have increased processing power. Accordingly, increased storage and memory is needed to meet the devices'programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. As devices continue to scale down, there is a desire to improve the resistivity of the device. However, advanced design schemes often exhibit complex features, making deposition and isolation of conductive materials difficult to conduct without subjecting the conductive material to oxidation or nitridation. Thus, there is a need in the industry to improve one or more features of advanced memory devices.

### BRIEF SUMMARY

The present technology is generally directed to methods and systems for forming advanced memory devices. Methods include depositing a dummy material on a dielectric material layer, where the dielectric material layer is formed over a first sidewall, a second sidewall, and a bottom surface, of one or more features. Methods include where the first sidewall is spaced apart from the second sidewall and the bottom surface is disposed between the first sidewall and the second sidewall, and the dummy material is deposited on the first sidewall, the second sidewall, and the bottom surface. Methods include filling a gap formed between the dummy material on the first sidewall and the dummy material on the second sidewall with a sacrificial isolation material. Methods include removing at least a portion of the bottom surface, exposing at least a portion of the dummy material and the sacrificial isolation material. Methods include removing the sacrificial isolation material and at least a portion of the dummy material, and selectively depositing a conductive material on a remaining portion of the dummy material.

In embodiments, methods include filling a gap between adjacent portions of the conductive material with a final gap fill material. Furthermore, in embodiments, methods include forming an air gap between adjacent portions of the conductive material. In more embodiments, methods include recessing the dummy material and the sacrificial isolation material, prior to removing at least a portion of the bottom surface. Additionally or alternatively, methods include filling the recess with one or more dielectric materials. In embodiments, methods include recessing the dummy material formed on the bottom surface and at least a portion of the sacrificial isolation material adjacent to the conductive material formed on the bottom surface. Moreover, in embodiments, the recessing includes depositing a self-aligned cap prior to recessing. In further embodiments, the dummy material is recessed with the sacrificial isolation material, is recessed after recessing the sacrificial isolation material, or is recessed before recessing the sacrificial isolation material. Embodiments include where the conductive material is deposited utilizing a selective atomic layer deposition process, a selective chemical vapor deposition process, or a combination thereof. In yet more embodiments, the conductive material is only deposited over the remaining portion of the dummy material. In embodiments, removing the sacrificial isolation material and the at least a portion of the dummy material, and selectively depositing the conductive material are conducted without a vacuum break. Furthermore, in embodiments, the dummy material includes titanium nitride, titanium silicon nitride, polycrystalline silicon, molybdenum nitride, molybdenum silicide, titanium, tantalum, ruthenium, tungsten, molybdenum, platinum, nickel, cobalt, tantalum nitride, tungsten nitride, niobium nitride, titanium aluminide, titanium aluminum nitride, titanium silicide, titanium silicon nitride, tantalum silicide, tantalum silicon nitride, ruthenium titanium nitride, nickel silicide, cobalt silicide, iridium oxide, ruthenium oxide or a combination thereof, and combinations thereof. In embodiments, the sacrificial isolation material comprises carbon, doped or undoped silicon, doped or undoped silicon germanium, titanium nitride, titanium silicide, titanium oxide, aluminum oxide, tungsten oxide, tungsten carbide, tungsten silicide, tungsten carbon nitride, zirconium oxide, and combinations thereof. Moreover, in embodiments, the conductive material includes titanium nitride, titanium silicon nitride, polycrystalline silicon, molybdenum nitride, doped or undoped molybdenum silicide, titanium, tantalum, ruthenium, tungsten, molybdenum, platinum, nickel, cobalt, tantalum nitride, tungsten nitride, tungsten silicide, niobium nitride, titanium aluminide, titanium aluminum nitride, titanium silicide, titanium nitride, titanium silicon nitride, tantalum silicide, tantalum silicon nitride, ruthenium titanium nitride, nickel silicide, cobalt silicide, iridium oxide, ruthenium oxide, ruthenium silicide, ruthenium nitride, alloys thereof, or combinations thereof. In embodiments, the final gap fill material comprises silicon oxide, silicon nitride, silicon oxynitride, silicon oxycarbonitride, silicon oxycarbide, silicon carbon nitride, a low-k material, and combinations thereof.

The present technology is also generally directed to methods of forming an advanced memory device. Methods include depositing a dummy material on a first sidewall, a second sidewall, and a bottom surface, of one or more features, where the first sidewall is spaced apart from the second sidewall and the bottom surface is disposed between the first sidewall and the second sidewall. Methods include where a first channel is adjacent to the first sidewall and a second channel is adjacent to the second sidewall. Methods include filling a gap formed between the dummy material on the first sidewall and the dummy material on the second sidewall with a sacrificial isolation material and flipping the advanced memory device. Methods include forming a dielectric cap over at least the first channel and the second channel and removing at least a portion of the bottom surface, exposing at least a portion of the dummy material and the sacrificial isolation material. Methods include removing the sacrificial isolation material and at least a portion of the dummy material and selectively depositing a conductive material on a remaining portion of the dummy material. In embodiments, the dummy material comprises molybdenum, tungsten, or a combination thereof.

The present technology is also generally directed to semiconductor processing systems. Systems include a system controller configured to form a dielectric material layer over a first sidewall, second sidewall, and a bottom surface of a feature, in a first processing chamber. Systems include a system controller configured to deposit a dummy material on the dielectric material layer on the first sidewall, the second sidewall, and the bottom surface. Systems include a system controller configured fill a gap formed between the dummy material on the first sidewall and the dummy material on the second sidewall with a sacrificial isolation material. Systems include a system controller configured remove at least a portion of the bottom surface, exposing at least a portion of the dummy material formed on the bottom surface. Systems include a system controller configured remove the sacrificial isolation material and at least a portion of the dummy material and selectively deposit a conductive material on a remaining portion of the dummy material.

In embodiments, a second processing chamber, a third processing chamber, and an optional fourth processing chamber, are contained within a cluster tool having a shared vacuum environment; and the system is configured to perform one or more operations in the second processing chamber or third processing chamber. Furthermore, in embodiments, the system controller is further configured to fill a gap between adjacent portions of the conductive material with a final gap fill material.

Such technology may provide numerous benefits over conventional systems and techniques. For example, the processes and systems may allow the use of low resistivity materials for power lines and/or signal lines with little to no damage, oxidation, or nitridation forming during processing. Additionally, the processes and systems may significantly improve electrical properties of the dielectric isolation materials, such as high break down voltage, low leakage and long term stability, by allowing the separation of high resistivity power line and signal line materials without damaging or degrading the materials during processing. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a schematic view of a semiconductor structure according to embodiments of the present technology.

FIG. 3B shows a schematic view of a semiconductor structure according to embodiments of the present technology.

FIG. 3C shows a schematic view of a semiconductor structure according to embodiments of the present technology.

FIG. 3D shows a schematic view of a semiconductor structure according to embodiments of the present technology.

FIG. 3E shows a schematic view of a semiconductor structure according to embodiments of the present technology.

FIG. 3F shows a schematic view of a semiconductor structure according to embodiments of the present technology.

FIG. 3G shows a schematic view of a semiconductor structure according to embodiments of the present technology.

FIG. 3H shows a schematic view of a semiconductor structure according to embodiments of the present technology.

FIG. 3I shows a schematic view of a semiconductor structure according to embodiments of the present technology.

FIG. 3J shows a schematic view of a semiconductor structure according to embodiments of the present technology.

FIG. 3K shows a schematic view of a semiconductor structure according to embodiments of the present technology.

FIG. 3L shows a schematic view of a semiconductor structure according to embodiments of the present technology.

FIG. 3M shows a schematic view of a semiconductor structure according to embodiments of the present technology.

FIG. 4A shows a schematic view of a semiconductor structure according to embodiments of the present technology.

FIG. 4B shows a schematic view of a semiconductor structure according to embodiments of the present technology.

FIG. 4C shows a schematic view of a semiconductor structure according to embodiments of the present technology.

FIG. 4D shows a schematic view of a semiconductor structure according to embodiments of the present technology.

FIG. 4E shows a schematic view of a semiconductor structure according to embodiments of the present technology.

FIG. 4F shows a schematic view of a semiconductor structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities have been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, advanced memory structures, including vertical cell structures such as 4F² DRAM, 6F² DRAM, 3D NAND, 3D DRAM, junction-less SONOS memory, floating body cell memory, oxide semiconductor memory, ferroelectric memory, and other devices having complex features and a desire for lower resistivity materials, as examples, come with their own challenges. For instance, there is a desire to utilize low resistivity conductive materials in advanced memory devices, such as for forming signal or power lines, which may also be in the form of sheets. However, low resistivity conductive materials, such as molybdenum, ruthenium, tungsten, titanium, titanium nitride, iridium, rhodium, and the like, are difficult to isolate in their thin film forms (deposited or etched), as they easily undergo oxidation and/or nitridation when left exposed, or adjacent to a nitride or oxygen containing material, and are also susceptible to degradation during high temperature processing. The difficulties of using low resistivity materials are further compounded by the fact that suitable isolation materials often cannot handle thermal processing that occurs after isolation, such as dielectric or metal depositions, silicide formation, and junction activation, as examples. This is problematic, as, when forming metallic signal or power lines, it is necessary to not only electrically separate the conductive materials in order to isolate the neighboring cells and protect the metallic signal or power line during processing but also maintain good electrical properties of the dielectric isolation materials, such as high break down voltage, low leakage and long term stability. Thus, existing processes have failed to provide methods of forming electrically isolated conductive signal or power lines, such as wordlines or bitlines, from low resistivity conductive materials without damaging the conductive material properties, such as by oxidation or nitridation of the surface of the conductive material.

The present technology overcomes these and other problems by depositing a dummy signal or power line material and sacrificial isolation material, and replacing some or all of the dummy signal or power line material and sacrificial isolation material during backside processing. Namely, by utilizing a dummy signal or power line material, oxidation or nitridation of the final low resistivity material is prevented during processing, as the low resistivity signal line or power line material is not introduced until after some or all high thermal budget processes are complete. Furthermore, as the initial isolation material is sacrificial, it allows the choice of more stable materials, not limited to dielectrics, that can sustain the thermal budget of the subsequent operations as long as the material is thermally compatible with the dummy material. Similarly, as the dummy signal or power line material is at least partially removed and replaced with low resistivity conductive materials after high thermal budget operations, sensitive materials may be utilized as low resistivity conductive materials. Moreover, as the replacement of the sacrificial isolation material occurs as part of backside processing, which occurs after completion of high thermal budget operations, a greater range of final gap fill materials such as low k dielectrics may be utilized, allowing for further improvements in electrical performance.

Although the remaining disclosure will routinely identify specific deposition and etch processes utilized for forming vertical cell access array transistors (VCAATs), such as a 4F² DRAM device, it will be readily understood that the systems and methods are equally applicable to other memory devices, including 6F² DRAM arrays, 3D NAND, and/or 3D DRAM device, junction-less SONOS memory, floating body cell memory, oxide semiconductor memory, ferroelectric memory, and other devices having high aspect ratio features, and orientations thereof, as well as processes for forming such devices. Accordingly, the technology should not be considered to be so limited as for use with these specific devices or systems alone. The disclosure will discuss one possible semiconductor device that may include one or more components, utilizing one or more power lines and/or signal lines according to embodiments of the present technology before additional variations and adjustments to this apparatus according to embodiments of the present technology are described.

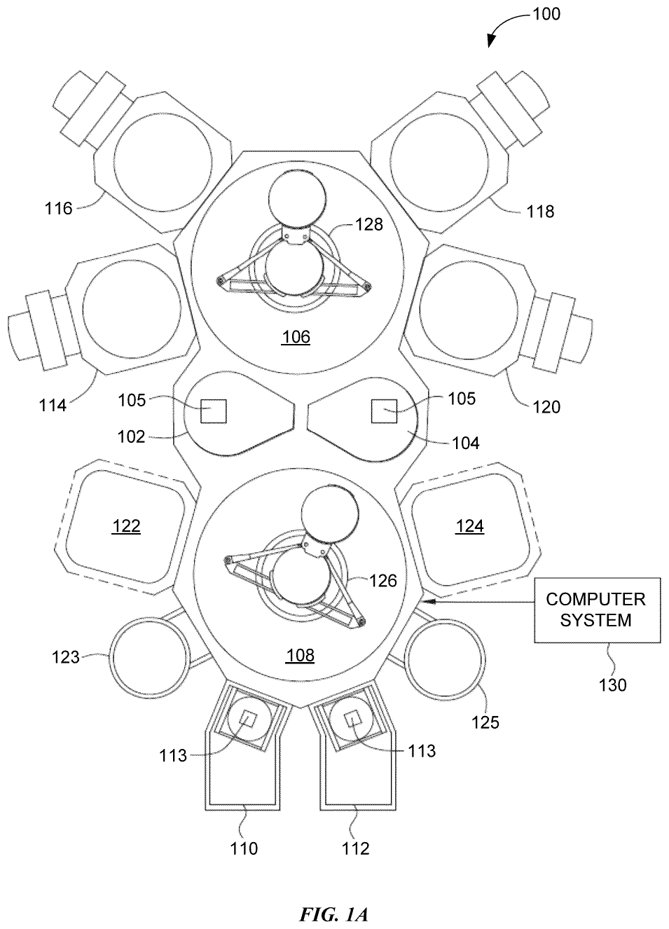

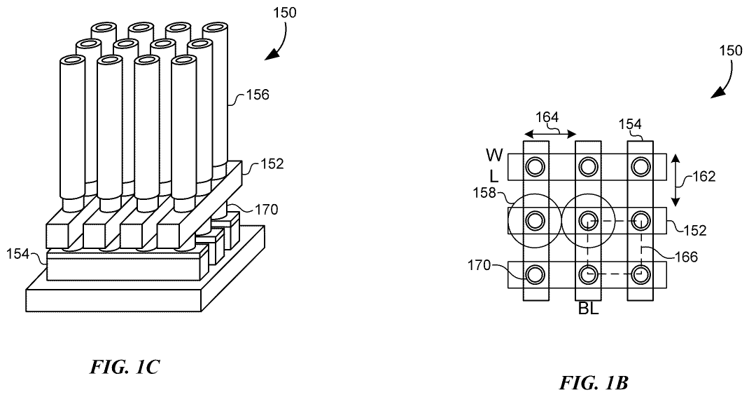

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108 and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystalline silicon, poly-crystalline silicon, amorphous silicon, silicon carbide, silicon germanium, germanium, an oxide semiconductor, including indium gallium zinc oxide, 2D materials including molybdenum disulfide, gallium nitride, carbon nanotubes, graphene, boron arsenide, combinations thereof, or any other substrates discussed in greater detail herein. Furthermore, dopants may be introduced based upon the device need, for any one or more of the materials discussed herein. This silicon channel may be formed by etching the substrate, as shown in the illustrated embodiments, or may be deposited onto the substrate, depending upon the desired device. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular generally orthogonal grid pattern (where “generally orthogonal”may be within about 10°from orthogonal, such as less than or about 7.5°, such as less than or about 5°, such as less than or about 2.5°, such as less than or about 1°from orthogonal, or any ranges or values therebetween, where “generally” may be utilized to similarly vary “vertical”, “horizontal” and the like) , it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

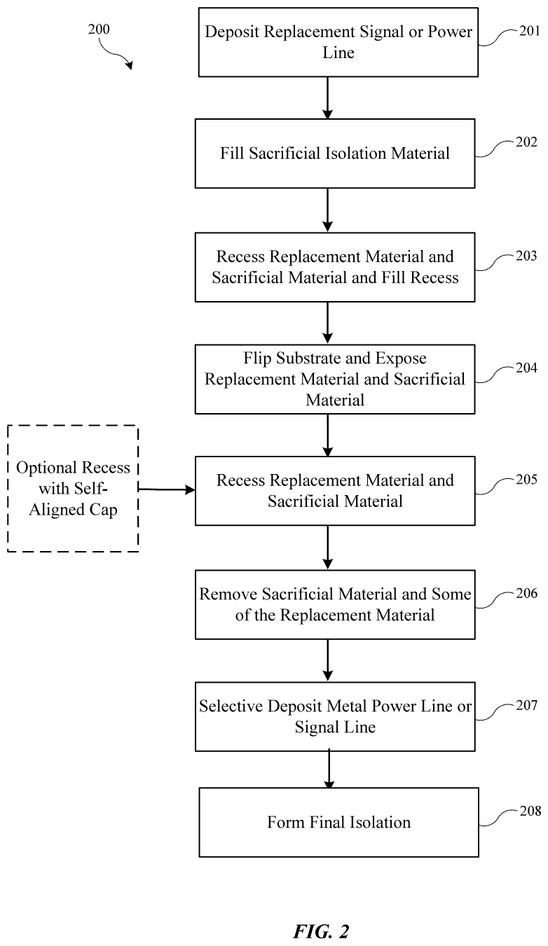

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized, as well as other orientations for non-vertical cell transistors.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in the Figures, the illustrations of which will be described in conjunction with the operations of method 200. It is to be understood that the Figures illustrate only partial schematic views, and a semiconductor substrate may include further components as illustrated in the figures, as well as alternative components, of any size or configuration that may still benefit from aspects of the present technology.

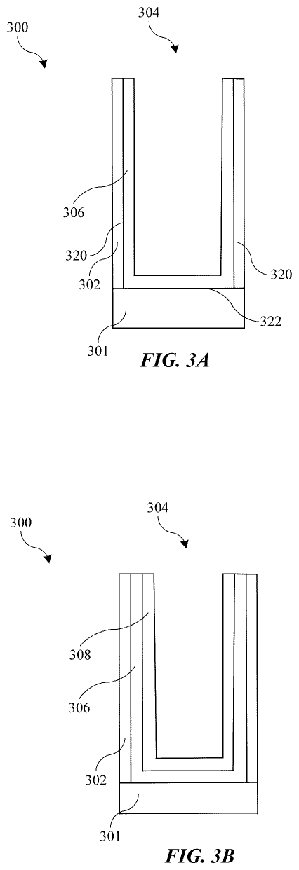

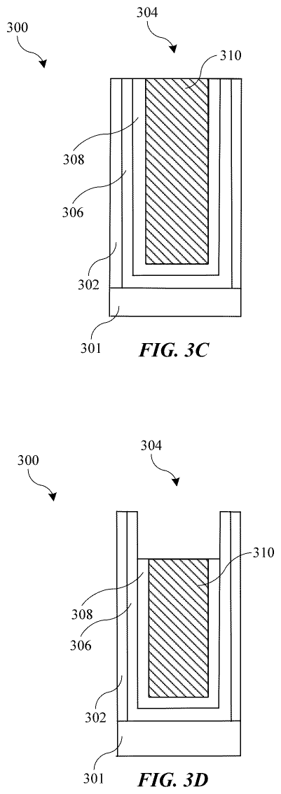

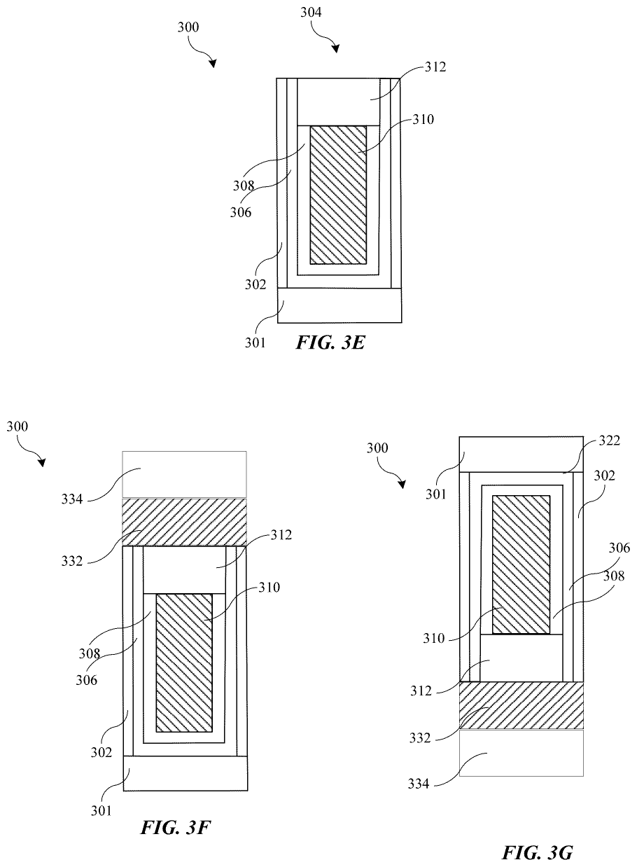

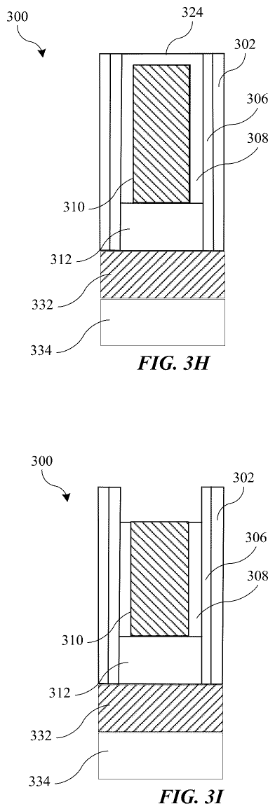

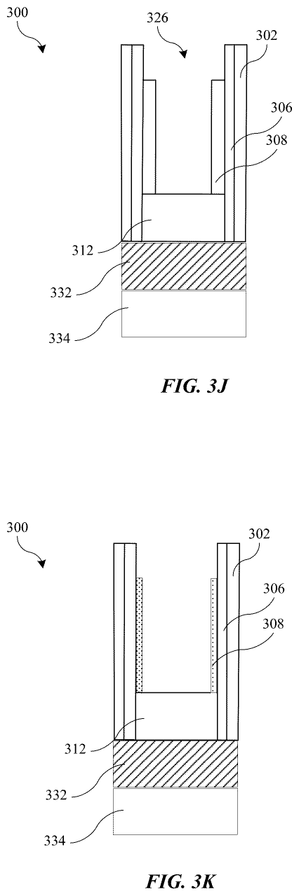

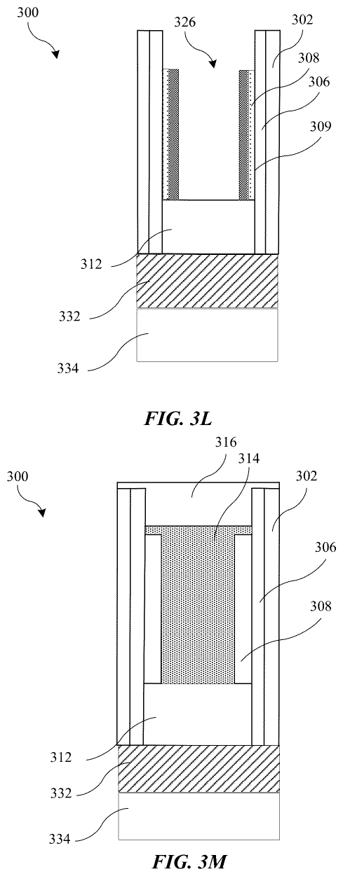

Method 200 may or may not involve optional operations to develop the semiconductor structure to a particular fabrication operation. It is to be understood that method 200 may be performed on any number of semiconductor structures 300 as illustrated in the Figures, including exemplary structures on which a selective deposition material may be formed. As illustrated in FIG. 3A semiconductor structure formed from a substrate material 301, which may be any number of materials, such as a base wafer or substrate made of silicon or silicon-containing materials, germanium, silicon germanium (SiGe), silicon on insulator (SOI), silicon germanium on insulator (SGOI), indium antimonide, lead telluride compounds, indium arsenide, indium phosphide, gallium arsenide, other substrate materials, as well as one or more materials that may be formed overlying the substrate during semiconductor processing.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

In embodiments, the substrate may include bulk substrates, epitaxially grown substrates, silicon, silicon germanium (SiGe), silicon on insulator (SOI), silicon germanium on insulator (SGOI), indium antimonide, lead telluride compound, indium arsenide, indium phosphide, and/or gallium arsenide, as well as any one or more substrate materials discussed above, on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

As illustrated in FIG. 3A, structure 300 is provided that contains two or more channels 302 with a feature 304 formed therebetween, which may be a shallow trench isolation, in embodiments. The two or more channels 302 may be formed from or on any one or more of the substrate materials discussed herein and have a dielectric material 306 formed thereon. In embodiments, suitable dielectric materials may include one or more gate oxides, one or more high k materials, as well as stacks or combinations thereof. In embodiments, the dielectric material 306 may include one or more layers of a SiO gate oxide, a SiO—SiN—SiO stack, a SiON layer, a high k material such as hafnium oxide, zirconium oxide, hafnium zirconium oxide, aluminum oxide, zirconium aluminum oxide hafnium aluminum oxide, zirconium niobium oxide, hafnium zirconium aluminum oxide, or combinations thereof. As illustrated, the dielectric material 306 may be formed over opposed first and second sidewalls 320 of the feature, as well as on bottom surface 322. While bottom surface 322 is shown as an interface between the one or more channels 302 and substrate 301, in embodiments, if the channels 302 are formed from the substrate 301, no physical interface may be presence. Instead, bottom surface 322 may illustrate a location of the substrate material during frontside operations. In embodiments, structure 300 may be a portion of a vertical channel array transistor, such as a 4F² DRAM array transistor, as well as a portion of any one or more of the advanced memory devices discussed herein and may therefore contain a different feature that the channel orientation discussed in the illustrations herein.

FIG. 3B illustrates depositing a dummy material 308 over the dielectric material 306 contained on the first and second sidewalls and bottom surface at operation 201. In embodiments, the dummy material 308 may be formed, such as by one or more deposition processes, directly over the dielectric material 306. In embodiments, the dummy material 308 may be a signal or power line material, such as a wordline and/or bitline material in embodiments. The dummy material may be a metal, or one or more other wordline and/or bitline materials, such as titanium, polysilicon, amorphous silicon, titanium nitride, titanium silicon nitride, titanium silicide, molybdenum nitride, molybdenum silicide, tungsten, tungsten nitride, tungsten carbonitride, tungsten silicide, or combinations thereof. In embodiments, the dummy material may be deposited at a thickness of greater than or about 1 nm, such as greater than or about 2 nm, greater than or about 3 nm, greater than or about 3.5 nm, greater than or about 4 nm, greater than or about 4.5 nm, greater than or about 5 nm, greater than or about 5.5 nm, greater than or about 6 nm, greater than or about 6.5 nm, such as greater than or about 7 nm, such as less than or about 14 nm, less than or about 12 nm, less than or about 10 nm, or any ranges or values therebetween.

In embodiments, dummy materials may include any one or more conductive materials having a low resistivity. In embodiments, the dummy material may be one or more materials suitable for initiating, or seeding, selective growth of one or more low resistive conductive materials. Furthermore, the dummy material 306 may be selected to meet the resistivity and work function requirements of the device in an event that the dummy material is not fully consumed during deposition of the conductive material. In embodiments, dummy materials may include titanium nitride, titanium silicon nitride, titanium aluminide, titanium aluminum nitride, polycrystalline silicon, amorphous silicon, molybdenum nitride, molybdenum silicide, titanium, ruthenium, tungsten, molybdenum, tantalum nitride, tungsten nitride, tungsten silicide, tungsten carbon nitride, tungsten silicon nitride, niobium nitride, titanium aluminum nitride, titanium silicon nitride, tantalum silicon nitride, ruthenium titanium nitride, lanthanum nitride, or a combination thereof.

Advantageously, dummy materials according to the present technology may be deposited utilizing one or more non-selective processes, also referred to as conformal deposition processes, such as ALD, or other processes known in the art. Furthermore, as will be discussed in greater detail below, such dummy materials also exhibit excellent etch selectivity compared to the surrounding structure. Regardless, in embodiments, dummy materials may include titanium nitride, titanium silicon nitride, polycrystalline silicon, amorphous silicon, molybdenum nitride, molybdenum silicide, tantalum nitride, tungsten nitride, niobium nitride, titanium aluminum nitride, titanium silicon nitride, tantalum silicon nitride, ruthenium titanium nitride, lanthanum nitride, or a combination thereof. In further embodiments, dummy materials may include titanium nitride, titanium silicon nitride, polycrystalline silicon, amorphous silicon, molybdenum nitride, molybdenum silicide, or a combination thereof. Moreover, in embodiments, the dummy materials include titanium nitride, titanium silicon nitride, amorphous silicon, polycrystalline silicon, molybdenum nitride, molybdenum silicide, or a combination thereof.

The dummy material may be deposited using any one or more of the deposition methods discussed above. In embodiments, the deposition may include selective deposition utilizing one or more processes as known in the art, such as ALD or CVD processes, as well as non-selective deposition processes. Namely, one or more precursors of the selected dummy material may be flowed alone or co-flowed with one or more carrier and/or inert gasses, into the chamber.

Before or after deposition of the dummy material 308 at operation 201, the semiconductor structure 300 may optionally undergo one or more treatment operations, such as an oxide removal, or reduction operation, a thermal or plasma treatment, a protective layer deposition, or combinations thereof. However, it should be understood that, in embodiments, no treatment operation(s) may be necessary. In some embodiments, one or more treatment operations may improve the compatibility of the dummy material with the sacrificial fill, for example, by enhancing adhesion and/or reducing reactions between the materials.

Regardless of whether any treatment is conducted, the deposition of the dummy material may be conducted at a temperature of greater than or about 200° C., such as greater than or about 210° C., such as greater than or about 220° C., such as greater than or about 230° C., such as greater than or about 240° C., such as greater than or about 250° C., such as greater than or about 260° C., such as greater than or about 270° C., such as greater than or about 280° C., such as greater than or about 290° C., such as greater than or about 300° C., such as greater than or about 310° C., such as greater than or about 320° C., such as greater than or about 330° C., such as greater than or about 340° C., such as greater than or about 350° C., such as greater than or about 360° C., such as greater than or about 370° C., such as greater than or about 380° C., such as greater than or about 390° C., such as greater than or about 400° C., such as greater than or about 410° C., such as greater than or about 420° C., such as greater than or about 430° C., such as greater than or about 440° C., such as greater than or about 450° C., such as greater than or about 460° C., such as greater than or about 470° C., such as greater than or about 480° C., such as greater than or about 490° C., such as greater than or about 500° C., such as greater than or about 510° C., such as greater than or about 520° C., such as greater than or about 530° C., such as greater than or about 540° C., such as greater than or about 550° C., such as greater than or about 560° C., such as greater than or about 570° C., such as greater than or about 580° C., such as greater than or about 590° C., such as greater than or about 600° C., such as greater than or about 610° C., such as greater than or about 620° C., such as greater than or about 630° C., such as greater than or about 640° C., such as greater than or about 650° C., such as greater than or about 660° C., such as greater than or about 670° C., such as greater than or about 680° C., such as greater than or about 690° C., such greater than or about 700° C., such as greater than or about 710° C., such as greater than or about 720° C., such as greater than or about 730° C., such as greater than or about 740° C., such as greater than or about 750° C., such as greater than or about 760° C., such as greater than or about 770° C., such as greater than or about 780° C., such as greater than or about 790° C., such as greater than or about 800° C., such as greater than or about 810° C., such as greater than or about 820° C., such as greater than or about 830° C., such as greater than or about 840° C., such as greater than or about 850° C., such as greater than or about 860° C., such as greater than or about 870° C., such as greater than or about 880° C., such as greater than or about 890° C., such as greater than or about 900° C., such as greater than or about 910° C., such as greater than or about 920° C., such as greater than or about 930° C., such as greater than or about 940° C., such as greater than or about 950° C., such as greater than or about 960° C., such as greater than or about 970° C., such as greater than or about 980° C., such as greater than or about 990° C., or up to about 1000° C. or less, or any ranges or values therebetween. Furthermore, it should be understood that the temperature or other chamber process conditions may be selected based upon the precursor(s) selected and/or the desired conductive material.

Furthermore, in embodiments, the dummy material may deposited at a chamber pressure of greater than or about 50 millitorr, such as greater than or about 500 millitorr, such as greater than or about 1 torr, such as greater than or about 5 torr, such as greater than or about 10 torr, such as greater than or about 15 torr, such as greater than or about 20 torr, such as greater than or about 25 torr, such as greater than or about 30 torr, such as greater than or about 35 torr, such as greater than or about 40 torr, such as greater than or about 45 torr, such as greater than or about 50 torr, such as greater than or about 75 torr, such as greater than or about 100 torr, such as greater than or about 150 torr, such as greater than or about 200 torr, such as greater than or about 250 torr, such as greater than or about 300 torr, such as greater than or about 350 torr, such as greater than or about 400 torr, such as greater than or about 450 torr, such as greater than or about 500 torr, such as greater than or about 550 torr, such a greater than or about 600 torr, such as greater than or about 650 torr, such as greater than or about 700 torr, up to about 760 torr, or any ranges or values therebetween.

Regardless of the process conditions utilized, as illustrated in FIG. 3C, in embodiments, a sacrificial isolation material 310 is filled into feature 304 (e.g. between adjacent portions of the dummy material 308) at operation 202. Advantageously, as the present technology provides a method for backside removal of the sacrificial isolation material 310, the sacrificial material can be either conductive or dielectric. Thus, the sacrificial isolation material may instead be selected based on compatibility with the dummy material and ease of removal at a subsequent processing operation, rather than based upon electrical isolation properties. In addition, changing of sacrificial material properties, be it physical, chemical or electrical, can be much less of a concern, as long as the materials remain structurally stable without causing undesired stress and remains non-reactive or minimally reactive with the dummy material during downstream high temperature processing operations. Thus, in embodiments, the sacrificial isolation material can include carbon, doped or undoped silicon, doped or undoped silicon germanium, silicon nitride, silicon oxide, silicon oxynitride, silicon oxycarbonitride, silicon carbon nitride, titanium nitride, titanium silicide, titanium oxide, aluminum oxide, tungsten oxide, tungsten carbide, tungsten silicide, tungsten carbon nitride, zirconium oxide, and combinations thereof.

As illustrated in FIG. 3D, after filling of the sacrificial isolation material, the sacrificial isolation material and the dummy material, are recessed to the desired depth based upon the target gate length, at operation 203. While a single step etch process is illustrated, where the sacrificial isolation material and the dummy material are etched simultaneously, it should be understood that a multi-step operation is also contemplated herein. Namely, in such embodiments, the sacrificial isolation material may be initially recessed to a desired depth, and then the dummy material is recessed, or alternatively, the dummy material is recessed, followed by recessing of the sacrificial isolation material. In addition, while not shown, it should be understood that, in embodiments, an etch back and/or a chemical mechanical polishing operation may be conducted to remove the sacrificial isolation material and dummy material from a top surface of the semiconductor structure prior to recessing the sacrificial material and dummy material. The recessing operation may be conducted by any etching processes as known in the art.

After recessing the sacrificial isolation material and the dummy material, a dielectric plug 312 is introduced into the recess as illustrated in FIG. 3E, at operation 203. However, as discussed above, features discussed herein, such as the recess and plug, may be relevant to the 4F² DRAM illustrations discussed herein, but may be other features depending upon the advanced memory device. In embodiments, suitable dielectric materials may include silicon nitride, silicon oxide, silicon oxynitride, SiOC, SiCN, and SiOCN, as well as stacks or combinations thereof.

It should be understood that other operations may be necessary based upon the advanced memory device selected, as illustrated by box 332 in FIG. 3F. For instance, while not shown, it should be clear that various components 332 may be formed prior to flipping, such as one or more capacitors, one or more bitlines, one or more metal and interconnection layers, or the like, may be formed prior to introduction of the secondary substrate 334, and may therefore intervene between plug 312 and secondary substrate 334. Nonetheless, it should be understood that a secondary substrate 334 may be glued, taped, or otherwise bonded to the one or more components 332, to act as a secondary “substrate” during backside processing, as illustrated by secondary substrate 334 in FIG. 3F. In embodiments, the secondary substrate may include silicon, quartz, sapphire, glass, indium phosphide, plastic and plastic based materials, combinations thereof, and the like. The secondary substrate 334 may contain one or more device components, such as one or more transistors, one or more metal interconnects and lines, one or more control circuits, one or more storage devices, or the like. It may also contain none of such and act purely as structural support. Furthermore, it should be clear that in embodiments, the secondary substrate 334 may be introduced prior to flipping, and may therefore be present in the orientation shown in FIG. 3G after flipping occurs. However, in embodiments, no secondary substrate may be necessary.

As illustrated in FIG. 3G, unlike prior processing methods, the present technology flips the orientation of the substrate at operation 204. Namely, as illustrated, bottom surface 322 is now disposed vertically above dielectric plug material 312. However, it should be clear that other orientations are contemplated based upon the structure 300. Nonetheless, the operations subsequent to flipping at operation 204 may be considered “backside processing”. Moreover, as illustrated in FIG. 3H, after flipping, the new top surface, formed by bottom surface 322, is ground and polished at operation 204, removing the substrate material 302 from the bottom surface 322 and exposing a bottom surface 324 (now the top surface) of the dummy material 308.

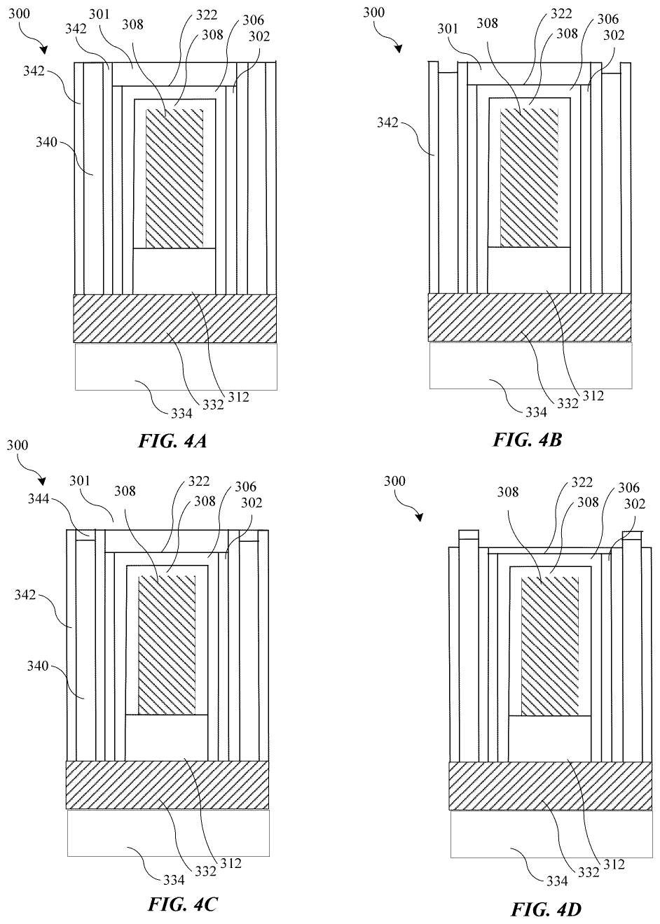

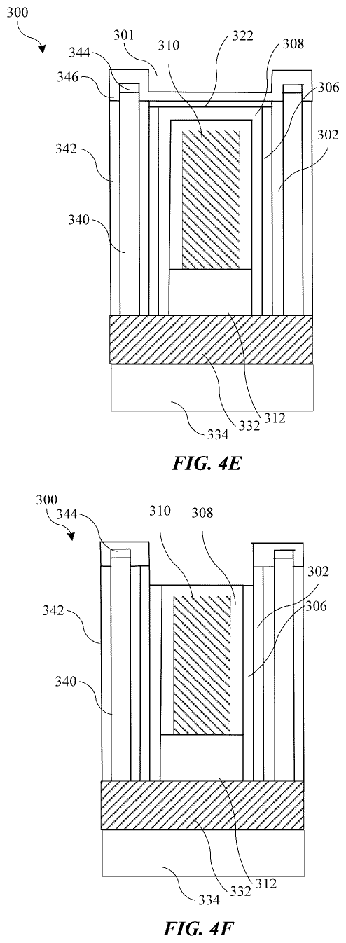

As illustrated in FIG. 3I, after exposing the backside of the dummy material 308, the dummy material 308 and sacrificial isolation material 310 are recessed to the desired depth based upon the target gate length, at operation 205. While a single step etch process is illustrated, where the sacrificial isolation material and the dummy material are etched simultaneously, it should be understood that an optional multi-step operation is also contemplated herein, which will be discussed in greater detail in regards to FIGS. 4A-4F. In embodiments, a further polishing or etch process may expose the sacrificial isolation material 310, following by a chemical etch process that may etch one or both of the sacrificial isolation material 310 and the dummy material 308, as an example only, isolating a first portion of the dummy material and a second portion of the dummy material. In addition, while not shown, it should be understood that, in embodiments, an etch back and/or a chemical mechanical polishing operation may be conducted to remove the sacrificial isolation material and dummy material from a bottom surface of the semiconductor structure prior to recessing the sacrificial material and dummy material, if material remains after polishing at operation 204. The recessing operation may be conducted by any etching processes as known in the art.

Before or after recessing to set the gate length of the dummy material, one or more processing operations may occur. For instance, in the case of a 4F² DRAM array, one or more word lines may be recessed, one or more junctions may be formed, one or more capacitors may be formed, one or more bitlines may be formed, one or more CMOS transistors may be formed, or all or a portion of the structure may be annealed. As discussed above, these processing operations may be one or more high thermal budget operations. Nonetheless, by maintaining the sacrificial isolation material and the dummy material within the feature during the one or more high thermal budget operations, both protection of the final low resistivity conductive material and protection of the final gap fill material is achieved. Namely, unlike prior attempts, the present technology provides methods and systems that prevent exposure of the low resistivity conductive material to oxygen or nitrogen, as well as thermal damage to the conductive material or final gap fill material during processing. This protects the isolation material from degradation, and also protects the low resistivity conductivity material from degradation or other damage during processing.

Nonetheless, as illustrated in FIG. 3J, the sacrificial isolation material 310 is removed, and as illustrated in FIG. 3K, some of the dummy material 308 is removed or trimmed at operation 206. In embodiments, any removal or trimming process as known in the art may be utilized. Namely, as discussed above, the sacrificial isolation material may be selected to be a material that is easily etched or removed, particularly related to the dummy material. Thus, in embodiments, one or more etching or removal processes may be utilized. In embodiments, one or more cleaning operations may be utilized to remove any oxides formed during upstream processes, or to convert the oxide back into the dummy material (e.g. TiO to TiN). In embodiments, the trimming operation 208 may remove any oxide present. In such a manner, if an exterior portion of the dummy material 308 was damaged, any oxidation, nitridation, or other processing damage may be removed from the exposed surface. As discussed above, in embodiments, the dummy material may be one or more materials suitable for initiating, or seeding, selective growth of one or more conductive materials. Thus, at least a portion of the dummy material 308 may be maintained on the one or more sidewalls.

After trimming and before selective deposition (such as immediately before, in embodiments) of the low resistivity conductive material, the semiconductor structure 300 may optionally undergo one or more treatment operations, such as an oxide removal or reduction operation (particularly if the structure is exposed to air between trimming and selective deposition), a thermal anneal or plasma treatment of the exposed surface of the dummy material, a selective deposition of one or more work function tuning layers (such as SiH₄ soaking in embodiments), a deposition-drive in-strip of a dipole material, or a combination thereof. Regardless, if one or more treatments are utilized, the surface may be prepared for selective deposition of the low resistivity conductive material, and allows for greater control of the Vt of the device.

However, it should be understood that, in embodiments, no cleaning operation(s) may be necessary. For instance, in embodiments, at least operations 205 and 206 may be conducted in the same cluster tool without breaking a vacuum environment, but it should be understood that some or all of the operations may be conducted in the same cluster tool. Moreover, in embodiments, one or more conductive materials may be formed from precursors that themselves etch the oxide, and therefore do not utilize an independent cleaning operation. For instance, as will be discussed in greater detail below, the conductive precursor may etch all or a portion of the dummy material, replacing a damaged or exposed surface of the dummy material without an intervening cleaning operation, or may even fully remove and replace the dummy material with the targeted conductive material(s).

Regardless of whether a cleaning operation is conducted, one or more low resistivity conductive materials 309 may be selectively deposited over the dummy material 308, as illustrated in FIG. 3L at operation 207. As illustrated, in embodiments, the one or more low resistivity conductive materials 309 may be formed directly on the dummy material 308. In the illustrated embodiment, the low resistivity conductive material is applied over the dummy material 308 such that some dummy material 308 is retained. However, in embodiments, the low resistivity conductive material may fully consumed the dummy material during formation, such that little to no dummy material is observed in the final structure. However, it should be understood that, in embodiments, some dummy material may remain between one or more of the sidewalls and the respective low resistivity conductive material, as illustrated. Furthermore, in embodiments, little to no conductive material may be formed over the exposed dielectric material 312. For instance, as discussed above, by carefully selecting the dummy material and conductive material, the conductive material may deposit selectively on the dummy material without growing on any exposed material other than the dummy material. Thus, as the dummy material has already undergone bottom etching, the conductive material may selectively deposit along the sidewalls, maintaining separation between adjacent conductive material layers 308 without requiring etching of the conductive material. Stated differently, in embodiments of the present technology, the conductive material, which may be a metallic signal or power line, such as a wordline and/or bitline material in embodiments, may only be formed on a dummy material surface even without etching the conductive material. As discussed above, in embodiments, the conductive material 308 may partially or completely remove and/or replace the dummy material 308. Thus, in embodiments, the thickness of the dummy material and conductive material, which may be all or substantially all conductive material after deposition, is greater than or about 1 nm, such as greater than or about 2 nm, greater than or about 3 nm, greater than or about 3.5 nm, greater than or about 4 nm, greater than or about 4.5 nm, greater than or about 5 nm, greater than or about 5.5 nm, greater than or about 6 nm, greater than or about 6.5 nm, such as greater than or about 7 nm, such as less than or about 14 nm, less than or about 12 nm, less than or about 10 nm, or any ranges or values therebetween.

In embodiments, conductive materials may include any one or more low resistivity conductive materials, as well as one or more conductive materials capable of selective growth over the dummy material selected. In embodiments, conductive materials may include titanium nitride, titanium silicon nitride, polycrystalline silicon, molybdenum nitride, doped or undoped molybdenum silicide, titanium, tantalum, ruthenium, tungsten, molybdenum, platinum, nickel, cobalt, tantalum nitride, tungsten nitride, tungsten silicide, niobium nitride, titanium aluminide, titanium aluminum nitride, titanium silicide, titanium nitride, titanium silicon nitride, tantalum silicide, tantalum silicon nitride, ruthenium titanium nitride, nickel silicide, cobalt silicide, iridium oxide, ruthenium oxide, ruthenium silicide, ruthenium nitride, alloys thereof, or combinations thereof. In embodiments, conductive materials may include one or more metals, such as titanium, tungsten, ruthenium, molybdenum, titanium nitride, titanium silicide, molybdenum nitride, doped or undoped molybdenum silicide, tungsten nitride, tungsten silicide, ruthenium oxide, ruthenium nitride, alloys thereof, or a combination thereof. In embodiments, the dummy material may include titanium nitride, the surface treatment may be a silane soak, and the conductive material may include molybdenum.

The conductive material may be selective deposited utilizing one or more processes as known in the art, such as utilizing ALD or CVD processes, in embodiments. Namely, one or more precursors of the selected conductive may be flowed alone, or co-flowed with one or more carrier and/or inert gasses, into the chamber after bottom etching, contacting the etched dummy material. For instance, when utilizing molybdenum as the conductive material, suitable precursors may include molybdenum chloride, molybdenum oxychloride, a molybdenum based metal organic compound, or combinations thereof. However, it should be clear that other precursors may be utilized based upon the conductive material selected.

Moreover, as discussed above, the precursor(s) may be selected so as to etch native oxide formed on the dummy material, such that an optional cleaning operation may not be necessary. For instance, when utilizing molybdenum as the conductive material, a molybdenum chloride precursor may be introduced which selectively etches the native oxide formed on the dummy material. After any oxide present on the liner is etched, the molybdenum chloride will selectively deposit on the dummy material. As a further example, when utilizing tungsten as the conductive material, a tungsten chloride precursor may be introduced which selectively etches the native oxide formed on the dummy material. After any oxide present on the liner is etched, the tungsten chloride will selectively deposit on the dummy material. Thus, the precursor material(s) may be selected to reduce the need for one or more cleaning operations.

The deposition may be conducted at a temperature of greater than or about 200° C., such as greater than or about 210° C., such as greater than or about 220° C., such as greater than or about 230° C., such as greater than or about 240° C., such as greater than or about 250° C., such as greater than or about 260° C., such as greater than or about 270° C., such as greater than or about 280° C., such as greater than or about 290° C., such as greater than or about 300° C., such as greater than or about 310° C., such as greater than or about 320° C., such as greater than or about 330° C., such as greater than or about 340° C., such as greater than or about 350° C., such as greater than or about 360° C., such as greater than or about 370° C., such as greater than or about 380° C., such as greater than or about 390° C., such as greater than or about 400° C., such as greater than or about 410° C., such as greater than or about 420° C., such as greater than or about 430° C., such as greater than or about 440° C., such as greater than or about 450° C., such as greater than or about 460° C., such as greater than or about 470° C., such as greater than or about 480° C., such as greater than or about 490° C., such as greater than or about 500° C., such as greater than or about 510° C., such as greater than or about 520° C., such as greater than or about 530° C., such as greater than or about 540° C., such as greater than or about 550° C., such as greater than or about 560° C., such as greater than or about 570° C., such as greater than or about 580° C., such as greater than or about 590° C., such as greater than or about 600° C., such as greater than or about 610° C., such as greater than or about 620° C., such as greater than or about 630° C., such as greater than or about 640° C., such as greater than or about 650° C., such as greater than or about 660° C., such as greater than or about 670° C., such as greater than or about 680° C., such as greater than or about 690° C., such greater than or about 700° C., such as greater than or about 710° C., such as greater than or about 720° C., such as greater than or about 730° C., such as greater than or about 740° C., such as greater than or about 750° C., such as greater than or about 760° C., such as greater than or about 770° C., such as greater than or about 780° C., such as greater than or about 790° C., such as greater than or about 800° C., such as greater than or about 810° C., such as greater than or about 820° C., such as greater than or about 830° C., such as greater than or about 840° C., such as greater than or about 850° C., such as greater than or about 860° C., such as greater than or about 870° C., such as greater than or about 880° C., such as greater than or about 890° C., such as greater than or about 900° C., such as greater than or about 910° C., such as greater than or about 920° C., such as greater than or about 930° C., such as greater than or about 940° C., such as greater than or about 950° C., such as greater than or about 960° C., such as greater than or about 970° C., such as greater than or about 980° C., such as greater than or about 990° C., or up to about 1000° C. or less, or any ranges or values therebetween. Furthermore, it should be understood that the temperature or other chamber process conditions may be selected based upon the precursor(s) selected and/or the desired conductive material.

Furthermore, in embodiments, the conductive material may deposited at a chamber pressure of greater than or about 50 millitorr, such as greater than or about 500 millitorr, such as greater than or about 1 torr, such as greater than or about 5 torr, such as greater than or about 10 torr, such as greater than or about 15 torr, such as greater than or about 20 torr, such as greater than or about 25 torr, such as greater than or about 30 torr, such as greater than or about 35 torr, such as greater than or about 40 torr, such as greater than or about 45 torr, such as greater than or about 50 torr, such as greater than or about 75 torr, such as greater than or about 100 torr, such as greater than or about 150 torr, such as greater than or about 200 torr, such as greater than or about 250 torr, such as greater than or about 300 torr, such as greater than or about 350 torr, such as greater than or about 400 torr, such as greater than or about 450 torr, such as greater than or about 500 torr, such as greater than or about 550 torr, such a greater than or about 600 torr, such as greater than or about 650 torr, such as greater than or about 700 torr, up to about 760 torr, or any ranges or values therebetween.

After formation of the low resistivity conductive material 309, the gap 326 may be filled with a final gap fill material 314, as illustrated in FIG. 3M, at operation 208. However, the “gap fill” may be considered to be a replacement of the sacrificial isolation material, as an air gap is now possible as a gap fill “material”. Nonetheless, the gap 326 may be filled by any suitable method as known in the art. In embodiments, the final gap fill material 314 may include silicon oxide, silicon nitride, silicon oxynitride, silicon oxycarbonitride, silicon oxycarbide, silicon carbon nitride, an air gap, low k materials, and combinations thereof. Namely, as discussed above, as the final gap fill material 314 and the low resistivity conductive material 309 are introduced after one or more high thermal budget operations, in embodiments, low k materials, and other materials previously believed unsuitable as isolation materials or conductive materials due to their poor thermal stability can be utilized using the methods and systems of the present technology. In addition, use of low k materials as final gap fill materials exhibit additional benefits of reducing parasitic coupling between neighboring conductive metals, therefore increase device operation speed.

The structure 300 may then re-enter a normal process flow. For instance, as illustrated, a dielectric plug 316 is introduced into the recess above the final gap fill material 314. In embodiments, suitable dielectric materials may include silicon nitride, silicon oxide, silicon oxynitride, SiOC, SiCN, and SiOCN, as well as stacks or combinations thereof. Nonetheless, one or more contacts may be formed, as well as other processing operations, based upon the final memory device.

Nonetheless, as discussed above, in embodiments, the recess of the dummy material and the sacrificial material may be conducted in a self-aligned manner, as will be discussed in greater detail in regards to FIGS. 4A to 4F. Such a recess operation may be beneficial, as it may allow for protection of neighboring features, such as one or more channels 302 and/or one or more signal lines or power lines 340. For instance, FIG. 4A may be or be similar to the structure of FIG. 3G, and FIGS. 4A-4F may serve as an alternative or an addition to FIGS. 3H and 3I. Nonetheless, FIG. 4A illustrates where the semiconductor structure 300 includes one or more signal lines or power lines 340 adjacent to the two or more channels 302 (which may be silicon, or any one or more of the channel materials discussed above). The structure may be polished or otherwise etched to expose a top surface of the one or more signal lines or power lines 340. In embodiments, the one or more signal lines or power lines 340 may be or include a polysilicon material and/or titanium nitride.

As illustrated in FIG. 4B, the one or more signal lines or power lines 340 may be selectively recessed. In such a manner, the one or more signal lines or power lines 340 may be recessed as compared to the surrounding dielectric materials 342 and/or substrate material 301 (such as silicon oxide, or any one or more of the substrate materials discussed above). In embodiments, the surrounding dielectric material 342 may include silicon oxide, or any one or more other dielectric materials discussed herein. As illustrated in FIG. 4C, this may allow for a plug material 344 to be deposited over the structure 300, such that the plug material 344 remains only in the recessed top surface of the one or more signal lines or power lines 340 when polished or etched back. In embodiments, plug materials 344 may include silicon nitride, as well as other dielectric materials discussed above.

By retaining the plug material 344 in the recessed top surface of the one or more signal lines or power lines 340, the plug material 344 may protect the one or more signal lines or power lines 340 during a dielectric etch operation. Namely, as illustrated in FIG. 4D, the dielectric material 342 and substrate material 301 may be etched, exposing a portion of the one or more signal lines or power lines 340. In such a manner, a dielectric spacer 346 may be applied over the semiconductor structure 300, as illustrated in FIG. 4E. In embodiments, dielectric spacers 346 may be or include silicon nitride, as well as other dielectric materials discussed herein. Due to the earlier capping and recessing, the dielectric spacer 346 may have a greater thickness over the one or more signal lines or power lines 340 as well as the adjacent channel material 302, such as by utilizing one or more non-conformal deposition processes. Due to the differences in thickness, a thinner portion overlying the dummy material 308 and sacrificial isolation material 310, may be fully removed during opening of the dielectric spacer 346 while retaining some or all of the dielectric spacer over the one or more signal lines or power lines 340 as well as the adjacent channel material 302. Thus, the channels 302 and/or the one or more signal lines or power lines 340 may be protected from damage while leaving the dummy material 308 and sacrificial isolation material 310 exposed for further processing. Thus, the structure illustrated in FIG. 4F may re-enter the process flow, such as at FIG. 3J, in embodiments, to form the low resistivity conductive material and isolation material, while leaving the one or more signal lines or power lines 340 as well as the adjacent channel material 302 protected.

It should be appreciated that the specific steps illustrated in the figures provide particular methods of forming 4F² DRAM arrays according to various embodiments but are also applicable to other advanced memory structures as discussed herein. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of forming a memory device, comprising:
depositing a dummy material on a dielectric material layer, wherein the dielectric material layer is formed over a first sidewall, a second sidewall, and a bottom surface, of one or more features, wherein the first sidewall is spaced apart from the second sidewall and the bottom surface is disposed between the first sidewall and the second sidewall, and the dummy material is deposited on the first sidewall, the second sidewall, and the bottom surface;
filling a gap formed between the dummy material on the first sidewall and the dummy material on the second sidewall with a sacrificial isolation material;
removing at least a portion of the bottom surface, exposing at least a portion of the dummy material and the sacrificial isolation material;
removing the sacrificial isolation material and at least a portion of the dummy material; and
selectively depositing a conductive material on a remaining portion of the dummy material.

2. The method of claim 1, further comprising filling a gap between adjacent portions of the conductive material with a final gap fill material.

3. The method of claim 1, further comprising forming an air gap between adjacent portions of the conductive material.

4. The method of claim 1, further comprising recessing the dummy material and the sacrificial isolation material, prior to removing at least a portion of the bottom surface.

5. The method of claim 4, further comprising filling the recess with one or more dielectric materials.

6. The method of claim 1, further comprising recessing the dummy material formed on the bottom surface and at least a portion of the sacrificial isolation material adjacent to the conductive material formed on the bottom surface.

7. The method of claim 5, wherein the recessing comprises depositing a self-aligned cap prior to recessing.

8. The method of claim 2, wherein the dummy material is recessed with the sacrificial isolation material, is recessed after recessing the sacrificial isolation material, or is recessed before recessing the sacrificial isolation material.

9. The method of claim 1, wherein the conductive material is deposited utilizing a selective atomic layer deposition process, a selective chemical vapor deposition process, or a combination thereof.

10. The method of claim 1, wherein the conductive material is only deposited over the remaining portion of the dummy material.

11. The method of claim 1, wherein removing the sacrificial isolation material and the at least a portion of the dummy material, and selectively depositing the conductive material are conducted without a vacuum break.

12. The method of claim 1, wherein the dummy material comprises titanium nitride, titanium silicon nitride, polycrystalline silicon, molybdenum nitride, molybdenum silicide, titanium, tantalum, ruthenium, tungsten, molybdenum, platinum, nickel, cobalt, tantalum nitride, tungsten nitride, niobium nitride, titanium aluminide, titanium aluminum nitride, titanium silicide, titanium silicon nitride, tantalum silicide, tantalum silicon nitride, ruthenium titanium nitride, nickel silicide, cobalt silicide, iridium oxide, ruthenium oxide or a combination thereof, and combinations thereof and/or wherein the sacrificial isolation material comprises carbon, doped or undoped silicon, doped or undoped silicon germanium, titanium nitride, titanium silicide, titanium oxide, aluminum oxide, tungsten oxide, tungsten carbide, tungsten silicide, tungsten carbon nitride, zirconium oxide, and combinations thereof.

13. The method of claim 2, wherein the conductive material comprises titanium nitride, titanium silicon nitride, polycrystalline silicon, molybdenum nitride, doped or undoped molybdenum silicide, titanium, tantalum, ruthenium, tungsten, molybdenum, platinum, nickel, cobalt, tantalum nitride, tungsten nitride, tungsten silicide, niobium nitride, titanium aluminide, titanium aluminum nitride, titanium silicide, titanium nitride, titanium silicon nitride, tantalum silicide, tantalum silicon nitride, ruthenium titanium nitride, nickel silicide, cobalt silicide, iridium oxide, ruthenium oxide, ruthenium silicide, ruthenium nitride, alloys thereof, or combinations thereof and/or wherein the final gap fill material comprises silicon oxide, silicon nitride, silicon oxynitride, silicon oxycarbonitride, silicon oxycarbide, silicon carbon nitride, a low-k material, and combinations thereof.

14. The method of claim 1, wherein removing at least a portion of the bottom surface is conducted from a wafer backside.

15. The method of claim 1, wherein the conductive material comprises forms a signal line or a power line for the memory device.

16. A method of forming a memory device, comprising:
depositing a dummy material on a first sidewall, a second sidewall, and a bottom surface, of one or more features, wherein the first sidewall is spaced apart from the second sidewall and the bottom surface is disposed between the first sidewall and the second sidewall, wherein a first channel is adjacent to the first sidewall and a second channel is adjacent to the second sidewall;
filling a gap formed between the dummy material on the first sidewall and the dummy material on the second sidewall with a sacrificial isolation material;
flipping the advanced memory device to begin backside processing;
forming a dielectric cap over at least the first channel and the second channel;
removing at least a portion of the bottom surface, exposing at least a portion of the dummy material and the sacrificial isolation material;
removing the sacrificial isolation material and at least a portion of the dummy material; and
selectively depositing a conductive material on a remaining portion of the dummy material.

17. The method of claim 16, wherein the dummy material comprises molybdenum, tungsten, or a combination thereof.

18. A semiconductor processing system, comprising:
a system controller configured to
form a dielectric material layer over a first sidewall, second sidewall, and a bottom surface of a feature, in a first processing chamber,
deposit a dummy material on the dielectric material layer on the first sidewall, the second sidewall, and the bottom surface,
fill a gap formed between the dummy material on the first sidewall and the dummy material on the second sidewall with a sacrificial isolation material,
remove at least a portion of the bottom surface, exposing at least a portion of the dummy material formed on the bottom surface;
remove the sacrificial isolation material and at least a portion of the dummy material; and
selectively deposit a conductive material on a remaining portion of the dummy material.

19. The semiconductor processing system of claim 18, wherein a second processing chamber, a third processing chamber, and an optional fourth processing chamber, are contained within a cluster tool having a shared vacuum environment; and wherein the system is configured to perform one or more operations in the second processing chamber or third processing chamber.

20. The semiconductor processing system of claim 18, wherein the system controller is further configured to fill a gap between adjacent portions of the conductive material with a final gap fill material.
